(19) United States
(12) Patent Application Publication
(10) Pub. No.: US 2022/0069196 A1
(43) Pub. Date: Mar. 3, 2022

(54) LEAD-FREE KNN-BASED PIEZOELECTRIC CERAMIC MATERIAL WITH TEXTURING, AND METHOD OF MAKING THE SAME

(71) Applicant: CTS Corporation, Lisle, IL (US)

(72) Inventors: Hakki Yegingil, Chicago, IL (US); Gerald T. Stranford, Albuquerque, NM (US); Anthony Phillip Seibert, Helsingor (DK); Ender Suvaci, Eskisehir (TR); Abdulkadir Murat Avci, Eskisehir (TR)

(73) Assignee: CTS Corporation, Lisle, IL (US)

(21) Appl. No.: 17/464,198

(22) Filed: Sep. 1, 2021

Related U.S. Application Data
(60) Provisional application No. 63/073,862, filed on Sep. 2, 2020.

(51) Int. Cl. H01L 41/187; H01L 41/316; H01L 41/39; C01G 33/00

(52) U.S. Cl. CPC H01L 41/1873; H01L 41/316; C01P 2004/61; C01G 33/006; C01P 2004/20; H01L 41/39

(57) ABSTRACT

A lead-free KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1, 0.5≤d≤1.0, 0.05≤e≤0.15, 0.01≤f≤0.09, 1≤g≤3. In one embodiment, the lead-free KNN-based piezoelectric material has a d₃₃>300 pm/V and a T_{curie}>250° C. In one embodiment, the d₃₃ and T_{curie} of the lead-free textured KNN-based piezoelectric material can be adjusted by creating phase boundaries of (i) orthorhombic to tetragonal (O-T), (ii) rhombohedral to orthorhombic (R-O), and (iii) orthorhombic to tetragonal (O-T). In one embodiment, the lead-free KNN-based piezoelectric material is textured with NaNbO₃ or Ba₂NaNb₅O₁₅ seeds which are platelet or acicular shaped. In one embodiment, the amount, orientation, or particle size distribution of the NaNbO₃ or Ba₂NaNb₅O₁₅ texturing seeds in the lead-free textured KNN-based piezoelectric material can be altered.

### CROSS-REFERENCE TO RELATED AND CO-PENDING APPLICATIONS

This application claims the benefit of the filing date and disclosure of U.S. Provisional Application Ser. No. 63/073, 862 filed on Sep. 2, 2020, the contents of which are entirely incorporated herein by reference as are all of references cited therein.

### FIELD OF THE INVENTION

This invention relates generally to a piezoelectric ceramic material and, more specifically, to a lead-free KNN-based piezoelectric ceramic material with texturing and the method of making the same.

### BACKGROUND OF THE INVENTION

Lead is one of the main constitutions of widely utilized Lead Zirconate Titanate (PZT) formulations and is typically anywhere from 40% to 65% in weight percentage in the formulations. Lead consumption in PZT based piezoelectric components can account for up to 100 tons per year of lead globally during processing of piezoelectric materials. European Commission (EC) has been reviewing lead material exemptions on a regular basis (every 3 years) and currently lead in piezoelectric ceramics is subject to exemptions and exclusions in specific medical and industrial applications.

Lead-based PZT formulations have superior properties to currently available lead-free piezoelectric materials in the marketplace and lead-free offerings cannot be used as drop-in replacements. For instance, although BaTiO₃ based lead-free systems are sometimes used in actuator applications at temperatures below 100° C., their properties quickly vanish above 100° C. (due to their lower Curie Temperatures) and their performance lacks behind lead based PZT systems. There is a need for lead-free piezoelectric ceramics that can maintain stability up to 200° C., while providing adequate performance. Lead-free potassium sodium niobate [(K_{0.5}Na_{0.5}NbO₃] based piezoelectric ceramics have been considered as an important alternative to replace lead-based systems in applications requiring a high d₃₃ (i.e., d₃₃>300 pm/V).

Saito et al. (Ref U.S. Pat. No. 6, 387, 295) has authored a patent on potassium sodium niobate-based compositions doped with lithium (Li), tantalum (Ta) and antimony (Sb) in which the intrinsic polymorphic phase transition (PPT) from orthorhombic to tetragonal crystal symmetry in alkaline niobate-based ceramics was shifted to room temperature, leading to improved characteristics in the ambient region for such KNN-LTS formulations.

Texturing of piezoelectric materials has also been shown to improve piezoelectric properties. Texturing can be introduced in ceramic systems by a process called Templated Grain Growth (TGG). This process involves alignment of the template (seed) particles within the ceramic body during green processing and the epitaxial nucleation and growth of the desired phase on those oriented templates during high temperature treatment. Therefore, an essential physical component in TGG is the template particles (i.e., large anisometric particles) which act as substrate for epitaxy and as seed for the exaggerated grain growth. The epitaxy dictates the crystallographic alignment of a small population of grains, which could be thought of as a population of oriented “exaggerated” grains. Thus, with further exaggerated grain growth, the volume fraction of textured material increases. Consequently, final polycrystalline ceramic exhibits textured microstructure, and hence, it shows single crystal-like properties.

The present invention is directed to a new lead-free KNN-based piezoelectric ceramic material that uses NaNbO₃ or Ba₂NaNb₅O₁₅ platelets or pellets as texturing seed particles.

### SUMMARY OF THE INVENTION

The present invention is generally directed to a lead-free textured KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1. 0.5≤d≤1.0, 0.05≤e≤0.15, 0.01≤f≤0.09, 1≤g≤3 and textured with NaNbO₃ or Ba₂NaNb₅O₁₅ seeds.

In one embodiment, the lead-free textured KNN-based piezoelectric material has a d₃₃>300 pmN and a T_{curie}>250° C.

In one embodiment, the chemical elements are present in the following weight % and mole fraction:

| Element | Weight % | Mole Fraction |
|---|---|---|
| Na | 5% to 6% | 0.2 to 0.3 Mole |
| K | 7% to 8% | 0.2 to 0.3 Mole |
| Nb | 42% to 46% | 0.4 to 0.5 Mole |
| Ta | 8% to 9% | 0.04 to 0.06 Mole |
| Sb | 7% to 8% | 0.05 to 0.07 Mole |
| O | 24% to 28% | 1.0 to 2.0 Mole |
| Li | Cannot be detected by | |
| | EDX | |

In one embodiment, the NaNbO₃ or Ba₂NaNb₅O₁₅ seeds are platelet shaped.

In one embodiment, the platelet shaped NaNbO₃ or Ba₂NaNb₅O₁₅ seeds have a length between approximately 5 to 15 microns, a width between approximately 5 to 15 microns, and an aspect ratio between approximately 25 to 30.

In one embodiment, the NaNbO₃ or Ba₂NaNb₅O₁₅ seeds are acicular shaped.

In one embodiment, the NaNbO₃ or Ba₂NaNb₅O₁₅ seeds are rod or needled shaped.

In one embodiment, the acicular shaped NaNbO₃ or Ba₂NaNb₅O₁₅ seeds have a length between approximately 5 to 40 microns, a width between approximately 2 to 7 microns, and an aspect ratio between approximately 2 to 16.

The present invention is also directed to a lead-free KNN-based piezoelectric material represented by the composition formula (KₐNa_{b}Li_{c})(Nb_{d}TaₑSb_{f})O_{g}, where 0.4a≤0.5, 0.5≤b≤0.6, 0.01≤c≤0.1, 0.5≤d≤1.0, 0.05≤e≤0.15, 0.01≤f≤0.09, 1≤g≤3.

In one embodiment, the lead-free KNN-based piezoelectric material is textured with NaNbO₃ or Ba₂NaNb₅O₁₅ seeds.

In one embodiment, the NaNbO₃ or Ba₂NaNb₅O₁₅ seeds are platelet shaped with a length between approximately 5 to 15 microns, a width between approximately 5 to 15 microns, and an aspect ratio between approximately 25 to 30.

In one embodiment, the NaNbO₃ or Ba₂NaNb₅O₁₅ seeds are acicular shaped and have a length between approximately 5 to 40 microns, a width between approximately 2 to 7 microns, and an aspect ratio between approximately 2 to 16.

In one embodiment, the lead-free KNN-based piezoelectric material has a d₃₃>300 pmN and a T_{curie}>250° C.

In one embodiment, the chemical elements are present in the following weight % and mole fraction:

| Element | Weight % | Mole Fraction |
|---|---|---|
| Na | 5% to 6% | 0.2 to 0.3 Mole |
| K | 7% to 8% | 0.2 to 0.3 Mole |
| Nb | 42% to 46% | 0.4 to 0.5 Mole |
| Ta | 8% to 9% | 0.04 to 0.06 Mole |
| Sb | 7% to 8% | 0.05 to 0.07 Mole |
| O | 24% to 28% | 1.0 to 2.0 Mole |
| Li | Cannot be detected by | |
| | EDX | |

The present invention is additionally directed to a method of making a lead-free textured KNN-based piezoelectric material comprising the steps of: a) providing a base lead-free KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1, 0.5≤d≤1.0, 0.05≤e≤0.15, 0.01≤f≤0.09, 1≤g≤3; and b) adding NaNbO₃ or Ba₂NaNb₅O₁₅ texturing seeds to the lead-free KNN-based piezoelectric material.

In one embodiment, the method further comprises the steps of adjusting the d₃₃ and T_{curie} of the base lead-free KNN-based piezoelectric material by creating phase boundaries of (i) orthorhombic to tetragonal (O-T), (ii) rhombohedral to orthorhombic (R-O), and (iii) orthorhomobic to tetragonal (O-T).

In one embodiment, the method further comprises the steps of mixing K₂CO₃, Na₂CO₃, Nb₂O₅, Li₂CO₃, Ta₂O₃, and Sb₂O₃ in an alcohol and ZrO₂ ball media.

In one embodiment, the method further comprises the steps of a) altering the amount of NaNbO₃ or Ba₂NaNb₅O₅ texturing seeds, b) altering the orientation of the NaNbO₃ or Ba₂NaNb₅O₁₅ texturing seeds, and c) altering the particle size distribution of the NaNbO₃ or Ba₂NaNb₅O₁₅ texturing seeds. In one embodiment, the NaNbO₃ or Ba₂NaNb₅O₁₅ texturing seeds are platelet or acicular shaped.

Other advantages and features of the present invention will be more readily apparent from the following detailed description of the preferred embodiment and method of the invention, the accompanying drawings, and the appended claims.

### BRIEF DESCRIPTION OF THE DRAWINGS

These and other features of the invention can best be understood by the description of the accompanying Figs. as follows: FIG. 1 is a flow diagram of the method for making a base lead-free KNN-based bulk piezoelectric ceramic material in accordance with the present invention;

FIG. 2 is an SEM photograph of the powder of the lead-free KNN-based bulk piezoelectric ceramic material in accordance with the present invention before milling;

FIG. 3 is an SEM photograph of the lead-free KNN-based bulk piezoelectric ceramic powder material in accordance with the present invention after milling;

FIG. 4 is an SEM photograph of the lead-free KNN-based bulk piezoelectric ceramic material in accordance with the present invention after sintering;

FIG. 5 is a graph of the XRD pattern of the sintered lead-free KNN-based bulk piezoelectric ceramic material in accordance with the present invention;

FIG. 6 is an EDX chart summarizing the chemical compositions by Weight % and Mole Fraction of the sintered lead-free KNN-based bulk piezoelectric ceramic material in accordance with the present invention;

FIG. 7 is an EDX graph of the sintered lead-free KNN-based bulk piezoelectric ceramic material in accordance with the present invention;

FIG. 8 is a flow diagram of the method for texturing of the lead-free KNN-based bulk piezoelectric ceramic material of the present invention with NaNbO₃ or Ba₂NaNb₅O₁₅ seed material to form the lead-free textured KNN-based piezoelectric ceramic material in accordance with the present invention;

FIG. 9 is an SEM photograph depicting the needle-shaped Ba₂NaNb₅O₁₅ texturing seeds of the lead-free textured KNN-based piezoelectric ceramic material in accordance with the present invention;

FIG. 10 is a graph of the XDRD pattern of the Ba₂NaNb₅O₁₅ texturing seeds of the lead-free textured KNN-based piezoelectric ceramic material in accordance with the present invention;

FIG. 11 is a graph of the particle size distribution of the Ba₂NaNb₅O₁₅ texturing seeds; and

FIG. 12 is an SEM photograph of the lead-free textured KNN-based piezoelectric ceramic material in accordance with the present invention.

### DESCRIPTION OF THE EMBODIMENT

The present invention is directed to a lead-free textured KNN-based piezoelectric ceramic material that has been developed via i) doping a base KNN based system with lithium (Li), tantalum (Ta) and antimony (Sb) in which the intrinsic polymorphic phase transition (PPT) from orthorhombic to tetragonal crystal symmetry in alkaline niobate-based ceramics was shifted to room temperature and ii) texturing with NaNbO₃ or Ba₂NaNb₅O₁₅ seed material.

FIG. 1 is a flow diagram of the method for making a base lead-free KNN-based piezoelectric ceramic bulk material or powder with the following chemical composition in accordance with the present invention: (KₐNa_{b}Li_{c})(Nb_{d}TaₑSb_{f})O_{g}, where 0.4a≤0.5, 0.5≤b≤0.6, 0.01≤c≤0.1. 0.5≤d≤1.0, 0.05≤e≤0.15, 0.01≤f≤0.09, 1≤g≤3.

Referring to FIG. 1, the method of making the base lead-free KNN-based bulk material or powder in accordance with the present invention comprises initially the step of mixing the following raw materials in the following noted amounts for making a synthesis bulk batch or matrix mixture or slurry of the lead-free KNN-based piezoelectric ceramic material in accordance with the present invention:

7 to 9 grams K₂CO₃

7 to 9 grams Na₂CO₃

29 to 32 grams Nb₂O₅

0.1 to 0.9 grams Li₂CO₃(dopant)

5 to 7 grams Ta₂O₃ (dopant)

2 to 4 grams Sb₂O₃ (dopant)
and in which the base material is the result of the reaction as follows:

XK₂CO₃+YNa₂CO₃+ZNb₂O₅+ALi₂CO₃+BTa₂O₅+CSb₂O₃ Where 0.1≤X≤0.5, 0.1≤Y≤0.5, 0.1≤Z≤0.8, 0.01≤A≤0.05, 0.01≤B≤0.08, and 0.01≤C≤0.08.

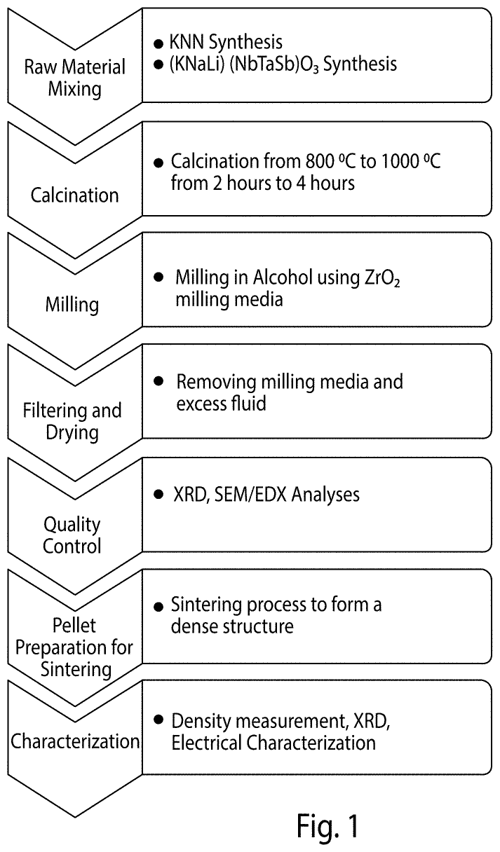

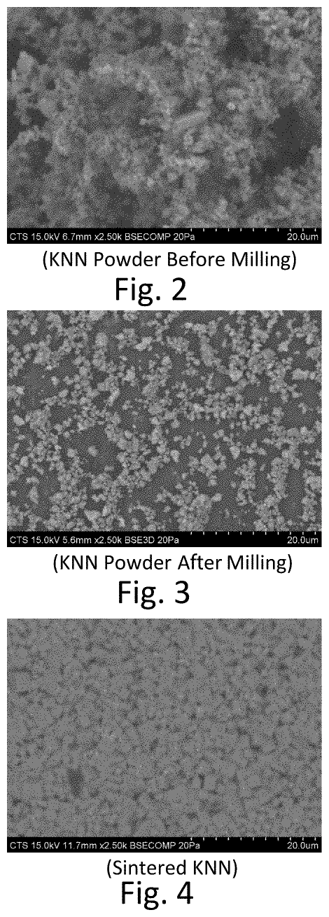

Still referring to FIG. 1, the method also includes the calcination of the base lead-free KNN-based piezoelectric ceramic bulk material at between approximately 800 to 1, 000° C. for approximately between two to four hours. FIG. 2 is an SEM photograph of the base lead-free KNN powder bulk material before milling.

Referring to FIG. 1, the method includes the step of milling for synthesizing the base lead-free KNN-based piezoelectric ceramic bulk material or mixture in an alcohol and Zirconia ZrO₂ (2 to 6 mm outer diamater) ball media combination. Preferably, attrition milling is used for the synthesizing of a base mixture powder with small size and narrow size distribution. FIG. 3 is an SEM photograph of the base lead-free KNN powder material after the milling step.

Referring to FIG. 1, the method also includes the step of filtering and drying of the base lead-free KNN-based piezoelectric ceramic bulk material or mixture to create a base lead-free KNN piezoelectric ceramic bulk material with the chemical composition noted above.

Still referring to FIG. 1, the method is followed by XRD/SEM/EDX analysis of the base lead-free KNN-based piezoelectric ceramic bulk material as shown in

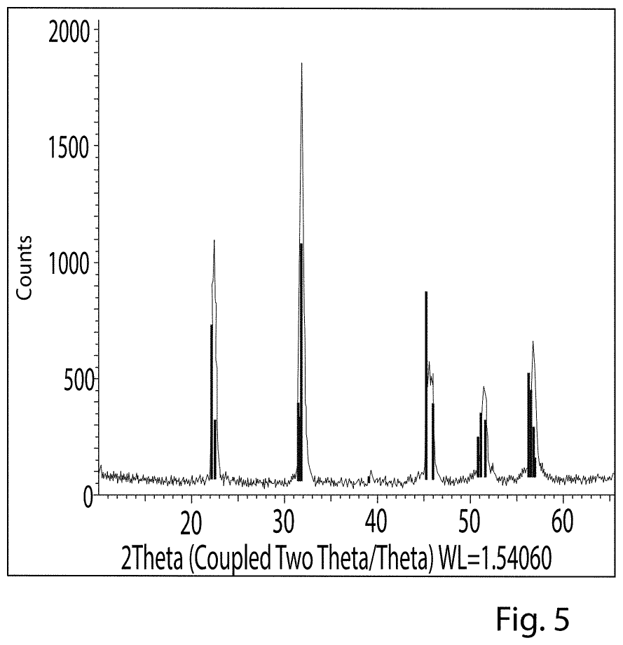

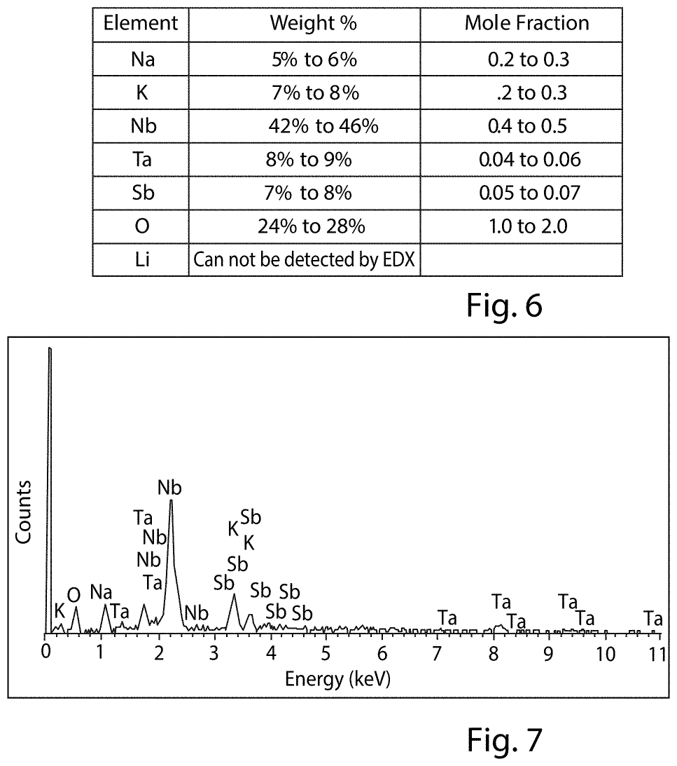

FIGS. 5-7 respectively and, more specifically, the analysis to confirm the presence of each of the respective elements of the base lead-free KNN-based bulk piezoelectric ceramic material in the weight % and mole fractions as described in the chart of FIG. 6.

The x-ray diffraction (XRD) pattern in FIG. 5 shows that modified KNN powder manufactured in accordance with the present invention is phase pure material with perovskite structure. The peaks are shifted slightly from the black bars, which are a reference pattern for unmodified KNN, showing that the modifications to the unmodified KNN cause the interplanar distance in the unit cell to decrease.

If the base lead-free KNN-based bulk piezoelectric ceramic material passes the XRD/SEM/EDX analysis, then the method with reference to FIG. 1 continues to the step of pellet preparation for TMA and sintering. FIG. 4 is an SEM photograph of the base lead-free KNN-based powder material following sintering.

If the base powder does not pass the XRD/SEM/EDX analysis, then the entire process is repeated.

The Mole fractions of the base powder in the chart of FIG. 6 are calculated using the following formula:

EDX=(K_{A}Na_{B}Lic)(Nb_{D}Ta_{E}Sb_{F})O_{G}

and

LF4=(K_{H}Na_{I}Li_{J})(Nb_{K}Ta_{L}Sb_{M})O_{N},

Where 0.3≤A≤0.5, 0.3≤B≤0.5, C≤0.1, 0.5≤D≤0.9, 0.01≤E≤0.09, 0.01≤F≤0.09, 1≤G≤3, 0.3≤H≤0.5, 0.3≤I≤0.5, J≤0.1, 0.5≤K≤0.9, 0.01≤L≤0.09, 0.01≤M≤0.09, 1≤N≤3.

FIG. 7 is a graph depicting the EDX spectrum of the base powder in accordance with the present invention.

Still referring to FIG. 1, the sintering step of the base lead-free KNN-based piezoelectric ceramic bulk material is followed by a density measurement, XRD and electrical characterization.

In accordance with one embodiment of the present invention, the base lead-free KNN-based piezoelectric ceramic bulk material has a d₃₃>300 pmN and a T_{curie}>250° C.

Additionally, in accordance with the present invention, the d₃₃ and Curie Temperature (T_{curie}) can be adjusted by creating phase boundaries of (i) Orthorhombic to Tetragonal (O-T), (ii) Rhombohedral-Orthorhombic (R-O), and (iii) Orthorhombic to Tetragonal (O-T). This can be achieved by doping the base lead-free KNN-based piezoelectric ceramic bulk material with the certain elements or compounds including, for example, Li, Ag, Zr, Hf, Ta, and Sb as describe above.

By varying the types of phase boundaries, KNN material can be shifted from Soft PZT to Hard PZT. Stated another way, it is understood that the properties of the base lead-free KNN-based piezoelectric ceramic bulk material can be altered with the use of the above-identified dopants.

The method of the present invention also includes the step of texturing the base lead-free KNN-based piezoelectric ceramic bulk material with NaNbO₃ or Ba₂NaNb₅O₁₅ seed material to create the KNN-based lead-free textured piezoelectric ceramic material in accordance with the present invention.

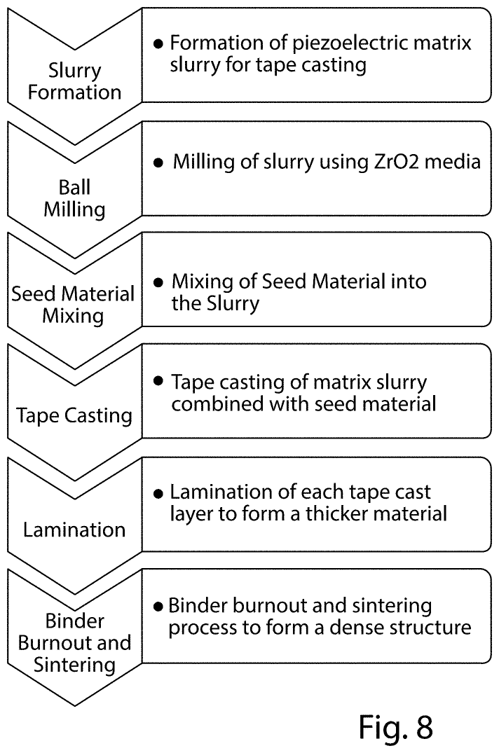

FIG. 8 is a flow diagram of the texturing process which includes the following steps: providing the KNN-based lead-free piezoelectric material matrix slurry as describe above; milling the KNN-based lead-free piezoelectric material slurry using ZrO₂ media; mixing the NaNbO₃ or Ba₂NaNb₅O₁₅ texturing seed material into the milled KNN-based lead-free piezoelectric material slurry; tape casting of the KNN-based lead-free piezoelectric material matrix slurry which has been textured with the NaNbO₃ or Ba₂NaNb₅O₁₅ seed material; laminating individual layers of KNN-based lead-free textured piezoelectric ceramic material to form a thicker KNN-based lead-free textured piezoelectric ceramic material; and conducting a binder burnout and sintering process on the KNN-based lead-free textured piezoelectric ceramic material for forming a KNN-based lead-free textured piezoelectric ceramic material with the desired dense structure.

The NaNbO₃ or Ba₂NaNb₅O₁₅ texturing seed material can be platelet (pellet) shaped or acicular (rod-like or needle-like) shaped.

In the embodiment where the NaNbO₃ or Ba₂NaNb₅O₁₅ texturing seed material is platelet (pellet) shaped, the textured seed particles have a length between approximately 5 to 15 microns; a width between approximately 5 to 15 microns; a thickness between approximately 0.2 to 0.5 microns, and an aspect ratio between approximately 25 to 30.

In the embodiment where the NaNbO₃ or Ba₂NaNb₅O₁₅ texturing seed material is acicular (rod-like or needle-like) shaped, the textured seed particles have a length between approximately 5 to 40 microns, a width between approximately 2 to 7 microns, and an aspect ratio between approximately 2 to 16.

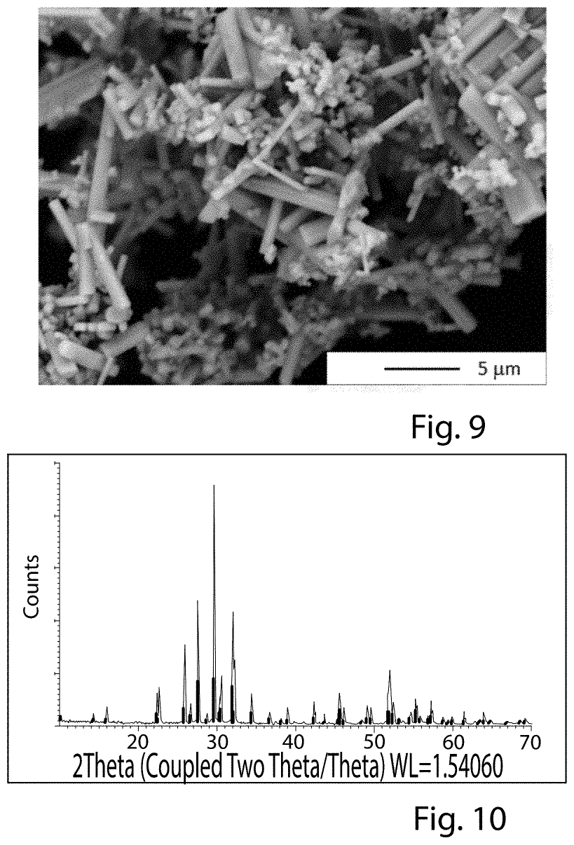

FIG. 9 is an SEM photograph of the acicular (rod-like or needle-like) shaped textured Ba₂NaNb₅O₁₅ seed material of the lead-free KNN-based piezoelectric ceramic material of the present invention.

FIG. 10 is a graph of the XRD pattern of the acicular (rod-like or needle-like) shaped Ba₂NaNb₅O₁₅ seed material of the lead-free KNN-based piezoelectric ceramic material of the present invention.

In particular, FIG. 10 shows the characteristic peaks of a tungsten bronze crystal structure with 110, 100, and 211 peaks at 10.1°, 22.4°, and 27.6° respectively. Analysis of the peak intensities to a normal polycrystalline BNN sample shows the intensities of (h00) peaks of rod-like Ba₂NaNb₅O₁₅ seed material are decreased compared to (hk0) and (0I0) peaks and suggests that the rods are aligned with their basal planes.

Although the acicular (rod-like or needle-like) shape is more applicable to Ba₂NaNb₅O₁₅seed material, it is understood that NaNbO₃ seed material can also be manufactured specifically as acicular (rod-like or needle-like) shaped.

Acicular shaped seed material, because of its rod-like or needle-like geometry, requires tailored tape cast processes to process the material. For instance, the viscosity of the slurry needs to be altered to ensure adequate orientation of the seed particles during tape casting occurs. Also, acicular (rod-like or needle-like) shaped seed particles tend to agglomerate more compared to that of the platelet shaped seed material. Pre-mixing of the seeds into the slurry has to accommodate this. Moreover, NaNbO₃ needle-like or rod-like shaped seed materials need to be oriented through its longitudinal direction for efficient textured grain growth.

The particles of the seed material also need to be filtered in terms of specific size requirements to better mix with the matrix raw material. Raw texturing seed material constitutes both fine and coarse seed particles and they need to be removed from the mix to enable a dense sintered material.

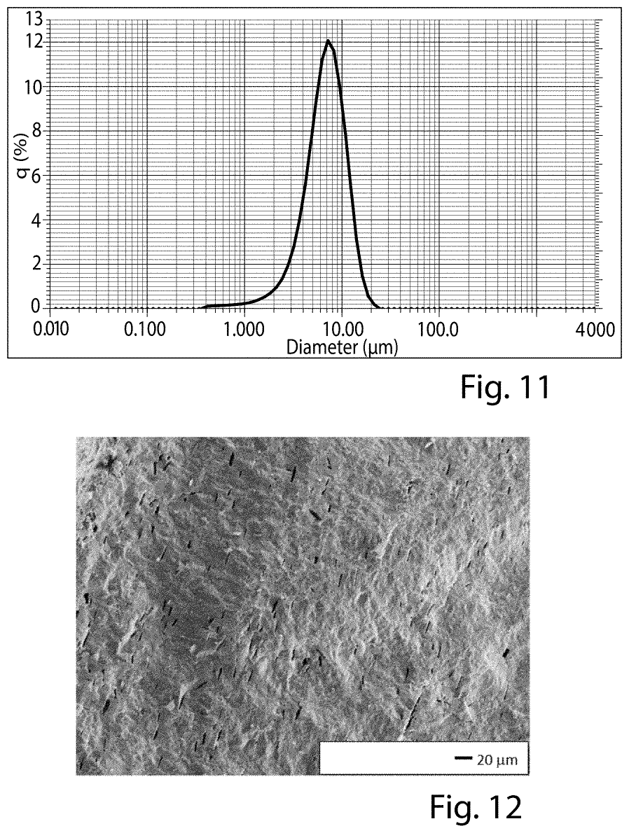

Specifically, FIG. 11 is a graph depicting the particle size distribution of the Ba₂NaNb₅O₁₅ texturing seed material in the lead-free textured KNN-based piezoelectric ceramic material of the present invention. In particular, and as shown in FIG. 11, Ba₂NaNb₅O₁₅ texturing seed material has majority of the seed particles distributed between 5 microns to 13 microns. With texturing using Ba₂NaNb₅O₁₅ texturing seed material, for specific KNN material formulations less than 5 microns of seed material could be filtered out.

FIG. 12 is an SEM photograph of a lead-free textured KNN-based piezoelectric ceramic material in accordance with the present invention.

It is also understood that the properties of the lead-free textured KNN-based piezoelectric ceramic material can be altered via adjustment of the amount, orientation, and particle size distribution of the textured seed material. Numerous variations and modifications of the lead-free textured KNN-based piezoelectric ceramic material and method of making the same may be affected without departing from the spirit and scope of the novel features of the invention. It is to be understood that no limitations with respect to the specific material and method described herein are intended or should be inferred. It is, of course, intended to cover by the appended claims all such modifications as fall within the scope of the claims.

What is claimed is:

1. A lead-free textured KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1, 0.5≤d≤0.1, 0.05≤e≤0.15, 0.01≤f≤0.09, 1≤g≤3 and textured with NaNbO₃ or Ba₂NaNb₅O₁₅ seeds.

2. The lead-free textured KNN-based piezoelectric material of claim 1 with a d₃₃>300 pm/V and a T_{curie}>250° C.

3. The lead-free textured KNN-based piezoelectric material of claim 1 wherein the chemical elements are present in the following weight % and mole fraction:

| Element | Weight % | Mole Fraction |
|---|---|---|
| Na | 5% to 6% | 0.2 to 0.3 Mole |
| K | 7% to 8% | 0.2 to 0.3 Mole |
| Nb | 42% to 46% | 0.4 to 0.5 Mole |
| Ta | 8% to 9% | 0.04 to 0.06 Mole |
| Sb | 7% to 8% | 0.05 to 0.07 Mole |
| | 24% to 28% | 1.0 to 2.0 Mole |
| Li | Cannot be detected by | |
| | EDX | |

4. The lead-free textured KNN-based piezoelectric material of claim 1 wherein the NaNbO₃ or Ba₂NaNb₅O₁₅ seeds are platelet shaped.

5. The lead-free textured KNN-based piezoelectric material of claim 4 wherein the platelet shaped NaNbO₃ or Ba₂NaNb₅O₁₅ seeds have a length between approximately 5 to 15 microns, a width between approximately 5 to 15 microns, and an aspect ratio between approximately 25 to 30.

6. The lead-free textured KNN-based piezoelectric material of claim 1 wherein the NaNbO₃ or Ba₂NaNb₅O₁₅ seeds are acicular shaped.

7. The lead-free textured KNN-based piezoelectric material of claim 6 wherein the NaNbO₃ or Ba₂NaNb₅O₁₅ seeds are rod or needled shaped.

8. The lead-free textured KNN-based piezoelectric material of claim 6 wherein the acicular shaped NaNbO₃ or Ba₂NaNb₅O₁₅ seeds have a length between approximately 5 to 40 microns, a width between approximately 2 to 7 microns, and an aspect ratio between approximately 2 to 16.

9. A lead-free KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1, 0.5≤d≤1.0, 0.05≤e≤0.15, 0.01≤f≤0.09, 1≤g≤3.

10. The lead-free KNN-based piezoelectric material of claim 9 further comprising texturing with NaNbO₃ or Ba₂NaNb₅O₁₅ seeds.

11. The lead-free KNN-based piezoelectric material of claim 10 wherein the NaNbO₃ or Ba₂NaNb₅O₁₅ seeds are platelet shaped with a length between approximately 5 to 15 microns, a width between approximately 5 to 15 microns, and an aspect ratio between approximately 25 to 30.

12. The lead-free textured KNN-based piezoelectric material of claim 10 wherein the NaNbO₃ or Ba₂NaNb₅O₁₅ seeds are acicular shaped and have a length between approximately 5 to 40 microns, a width between approximately 2 to 7 microns, and an aspect ratio between approximately 2 to 16.

13. The lead-free KNN-based piezoelectric material of claim 9 with a d₃₃>300 pm/V and a T_{curie}>250° C.

14. The lead-free KNN-based piezoelectric material of claim 9 in which the chemical elements are present in the following weight % and mole fraction:

| Element | Weight % | Mole Fraction |
|---|---|---|
| Na | 5% to 6% | 0.2 to 0.3 Mole |
| K | 7% to 8% | 0.2 to 0.3 Mole |
| Nb | 42% to 46% | 0.4 to 0.5 Mole |
| Ta | 8% to 9% | 0.04 to 0.06 Mole |
| Sb | 7% to 8% | 0.05 to 0.07 Mole |
| O | 24% to 28% | 1.0 to 2.0 Mole |
| Li | Cannot be detected by | |
| | EDX | |

15. A method of making a lead-free textured KNN-based piezoelectric material comprising the steps of:
a) providing a base lead-free KNN-based piezoelectric material represented by the composition formula (KₐNa_{b}Li_{c})(Nb_{d}TaₑSb_{f})O_{g}, where 0.4≤a≤0.5, 0.5≤b≤0.6, 0.01≤c≤0.1, 0.5≤d≤1.0, 0.05≤e≤0.15, 0.01≤f≤0.09, 1≤g≤3.
b) adding NaNbO₃ or Ba₂NaNb₅O₁₅ texturing seeds to the lead-free KNN-based piezoelectric material.

16. The method of claim 15 further comprising the steps of adjusting the d₃₃ and T_{curie} of the base lead-free KNN-based piezoelectric material by creating phase boundaries of (i) orthorhombic to tetragonal (O-T), (ii) rhombohedral to orthorhombic (R-O), and (iii) orthorhombic to tetragonal (O-T).

17. The method of claim 15 further comprising the steps of mixing K₂CO₃, Na₂CO₃, Nb₂O₅, Li₂CO₃, Ta₂O₃, and Sb₂O₃ in an alcohol and ZrO₂ ball media.

18. The method of claim 15 further comprising the steps:
a) altering the amount of NaNbO₃ or Ba₂NaNb₅O₁₅ texturing seeds;
b) altering the orientation of the NaNbO₃ or Ba₂NaNb₅O₁₅ texturing seeds; and
c) altering the particle size distribution of the NaNbO₃ or Ba₂NaNb₅O₁₅ texturing seeds.

19. The method of claim 15 wherein the NaNbO₃ or Ba₂NaNb₅O₁₅ texturing seeds are platelet or acicular shaped.
